(19) United States
(12) Patent Application Publication
(10) Pub. No.: US 2006/0088089 A1
(43) Pub. Date: Apr. 27, 2006

(54) Adaptive equalizer with dual loop adaptation mechanism

(75) Inventors: Srikanth Gondi, Los Angeles, CA (US); Benoit Roederer, San Jose, CA (US)

Correspondence Address: OLIFF & BERRIDGE, PLC, P.O. BOX 19928, ALEXANDRIA, VA, 22320, US

(73) Assignee: KAWASAKI MICROELECTRONICS AMERICA, INC., San Jose, CA (US)

(21) Appl. No.: 11/214,918

(22) Filed: Aug. 31, 2005

Related U.S. Application Data
(60) Provisional application No. 60/621,533, filed on Oct. 25, 2004.

(51) Int. Cl. H03K 5/159

(52) U.S. Cl. 375/232

(57) ABSTRACT

An adaptive equalizer may use dual loop adaptation to improve the performance of the equalizer. The first feedback loop may generate a boost control signal, based on the signal input to and output from a slicer. A second feedback loop may correct the swing amplitude of the slicer, so that the swing of the output matches the swing of the input.

### RELATED APPLICATIONS

This non-provisional application claims the benefit of U.S. Provisional Application No. 60/621,533 filed Oct. 25, 2004, and is related to U.S. application Ser. No. ______ (Attorney Docket No. 121447) and U.S. application Ser. No. ______ (Attorney Docket No. 121449), each of which is incorporate by reference in its entirety.

### BACKGROUND

This invention relates to systems and methods for improving the performance of adaptive equalizers.

Data which is transmitted through a communications channel suffers from distortion due to the frequency-dependent transmission properties of the channel. Skin effect losses and dielectric losses are common examples of frequency-dependent channel losses which can be imposed on the signal passing through the channel. The distortion of the signal at high frequencies can lead to intersymbol interference (ISI), wherein the rising edge of a subsequent data bit is superimposed on the falling edge of the previous data bit, leading to a smearing of the transition between bits. This smearing causes increased timing jitter and reduced amplitude. The increased timing jitter makes clock recovery more difficult, whereas the reduced amplitude degrades the bit error rate performance of the channel at the output.

The frequency-dependent losses may, in theory, be compensated by applying either a precompensation to the signal before the channel, or a frequency-dependent gain, or boost, to the signal at the exit of the channel. Precompensation adjusts the attributes of the input signal at the transmitter to compensate for known transmission properties of the channel. However, since the transmission properties of the channel are often not known a priori, the compensation is more commonly applied to the output of the channel as receiver equalization, referred to herein as equalization.

Equalizers adjust the output signal from a channel to reverse some of the effects of distortion of the channel on the data signal. Equalizers apply a frequency-dependent amplification to the signal, such that frequencies which have been transmitted with high loss are amplified relative to frequencies which have been transmitted with low loss. Adaptive equalizers adjust the frequency and amplitude of the boost they apply according to the losses occurring in the channel.

### SUMMARY

Equalizers in the multi-Gb/sec range have been implemented using expensive bipolar-CMOS technology. This makes high frequency equalizers very difficult to implement in cost-constrained, noisy environments, such as in microprocessors and memories on printed circuit boards (PCBs), backplane environments with a multitude of PCBs, server and networking equipment transferring data, and gigabit Ethernet applications.

A 10 Gb/sec adaptive equalizer may be fabricated using all CMOS processes. The adaptive equalizer may achieve improved performance by providing dual feedback loops, a first loop controlling the high frequency boost in an equalizer filter, and a second loop controlling the swing of a slicer used to evaluate the performance of the equalizer filter. Using the second feedback loop, variations in the output of the slicer may be corrected independently of a boost control signal. Such a dual feedback approach may yield a better correction of an equalized signal, for example, by correcting errors due only to operation of the slicer, rather than operation of the equalizer filter.

The adaptive equalizer may comprise an equalizer filter which provides an equalized waveform, and a slicer, which produces a high or low output level, depending on whether the equalized waveform exceeds a positive or negative threshold. The adaptive equalizer may further comprise a boost control feedback loop, which controls the boost of the equalizer filter, and a swing control feedback loop which controls swing between the high output level and the low output level of the slicer.

Various details are described in, or are apparent from, the following detailed description.

### BRIEF DESCRIPTION OF THE DRAWINGS

Various details are described with reference to the following figures, wherein:

FIG. 1 is a diagram of an exemplary equalizer operating in a data detection circuit;

FIG. 2 is a diagram of an exemplary equalizer adaptation scheme;

FIG. 3 shows the signal spectrum at an input and an output of a slicer;

FIG. 4 is a diagram of an exemplary equalizer using dual loop adaptation;

FIG. 5 shows an exemplary equalizer filter usable in the equalizer of FIG. 4;

FIG. 6 shows an exemplary boost stage usable in the equalizer filter of FIG. 5;

FIG. 7 shows an exemplary gain stage usable in the equalizer filter of FIG. 5;

FIG. 8 shows an exemplary slicer usable in the equalizer of FIG. 4;

FIG. 9 shows a comparison of characteristic time scales for a boost control signal relative to a swing control signal of the slicer of FIG. 8;

FIGS. 10-13 show measured results of the equalizer of FIG. 4 using a power supply at 1.2V;

FIG. 14-17 shows measured results of the equalizer of FIG. 4 using a power supply at 1.0V; and

FIG. 18 shows a photograph of an exemplary equalizer die.

### DETAILED DESCRIPTION OF EXEMPLARY EMBODIMENTS

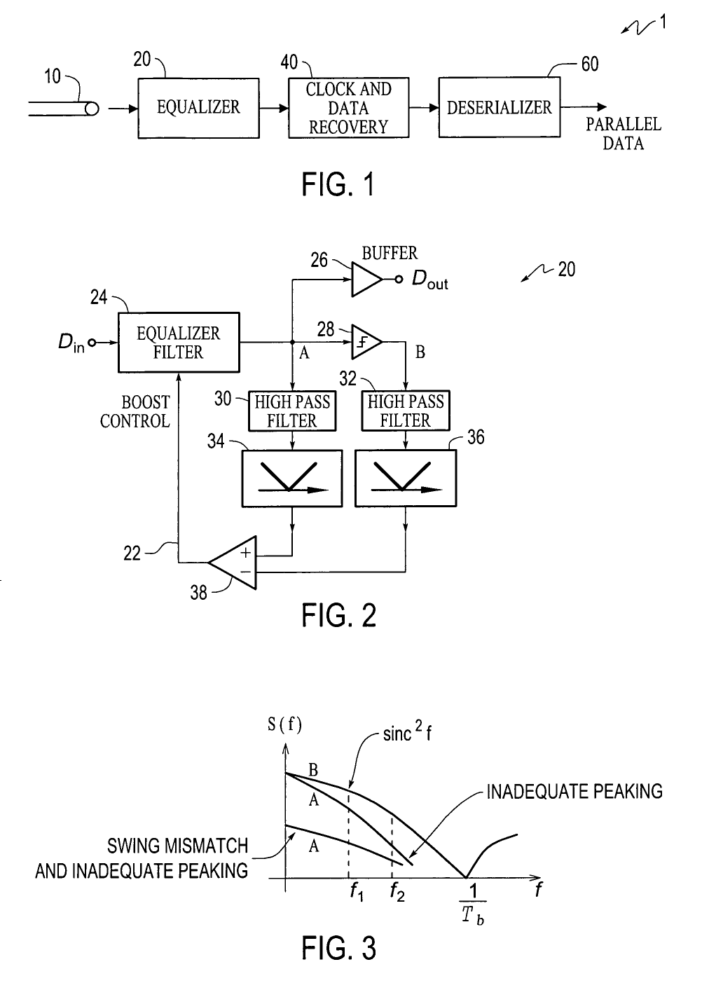

FIG. 1 is a diagram of an equalizer operating in a data detection circuit 1. Data may be transmitted over a channel 10, and the data signal may be distorted by the transmission characteristics of the channel. In particular, high frequency components, for example frequencies in excess of 500 MHz, of the data signal may be attenuated, whereas low frequency components, for example, frequencies less than 500 MHz, may pass through the channel with relatively little loss. As a result, an equalizer 20 may be placed in the data detection circuit 1, to provide gain (boost) to the high frequency components. After the equalizer 20, a clock and data recovery circuit 30 may accept the equalized signal and recover a data clock based on the equalized signal. For example, a phase-locked loop may be employed to generate a clock based on zero-crossings of the equalized data signal. The equalized data signal may then be sampled according to the occurrence of the data clock pulses, and the samples may be compared to a threshold, to determine if a bit is present, and, when present, the digital value of the bit. The data may then be transmitted to a data deserializer 40, that may arrange the data in a parallel format and may output the parallel data on parallel lines.

FIG. 2 is a diagram of an exemplary equalizer implementation which may be used in the data detection circuit 1 in FIG. 1. Equalizer 20 may use a single feedback loop 22 to control the boost of an equalizer filter 24. A boost control signal may control the frequency-dependent gain which may be applied to an input signal by the equalizer filter 24. Output of the equalizer filter 24 may be fed to an output buffer 26, a slicer 28, and a high pass filter 30. Slicer 28 may be a saturatinggain stage, which produces a high (+1) or a low (−1) output, depending on whether the positive-going equalized signal exceeds a positive threshold, or the negative-going equalized signal exceeds a negative threshold. The output of high pass filter 30 may be fed to a rectifier 34, which may invert a negative-going signal to a positive-going signal. The output of the slicer 28 may also fed to another high pass filter 32, and then to another rectifier 36. Outputs of the two rectifiers 34 and 36 may be coupled to inputs of an operational amplifier 38, which may compare a magnitude of a rectified output from high pass filter 30 to a magnitude of rectified output of high pass filter 32.

The effect of the high pass filter 32 may be to measure the slope of the input signal. Because output of the slicer 28, labeled B in FIG. 2 may have a slope which may depend on the response characteristics of slicer 28, and on the RC (resistance x capacitance) time constant of the output node of the slicer 28. Therefore, in general, the slicer output may have a different slope than the input signal, labeled A in FIG. 2. This effect is shown in FIG. 3, which shows the difference in spectral content of the output B of slicer 28 compared to the input A of slicer 28. In the region between f₁ and f₂ shown in FIG. 3, the output B of slicer 28 may have a higher amplitude than the input A to slicer 28. Therefore, when filtered by high pass filters 30 and 32, and rectified by rectifiers 34 and 36, the amplitude of the negative (inverting) input of the operational amplifier 38 may be larger than the amplitude of the positive (non-inverting) input to operational amplifier 38. Therefore, operational amplifier 38 may output a signal tending to increase the high frequency boost applied by the equalizer filter 24, until its inputs are equal. Therefore, the effect of feedback loop 22 may be to increase the high frequency boost of the equalizer filter 24 until the slope of the equalizer output signal is as steep as the slope of the slicer output signal. To the extent that the output of the equalizer 20 may fail to match the slope of the output of the slicer 28, an error exists which the operational amplifier 38 may attempt to remove by adjusting its output. This difference between output B of slicer 28 and input A of slicer 28 may be termed inadequate peaking.

However, FIG. 3 shows another source of potential error in the feedback circuit of FIG. 2. This error may occur if the swing of the output B of slicer 28 is different than the swing of the input A to slicer 28. This situation may occur because the swing of the output B may be determined by different parameters, such as the bias current, or tail current of the transistors and load resistor (not shown) of slicer 28. As shown in FIG. 3, this error is severe for all frequencies. In this situation where the low frequency swing mismatch error exists, the feedback loop 22 of FIG. 2 may not operate properly, because of the additional error in the input to the operational amplifier 38 due to the swing mismatch between A and B.

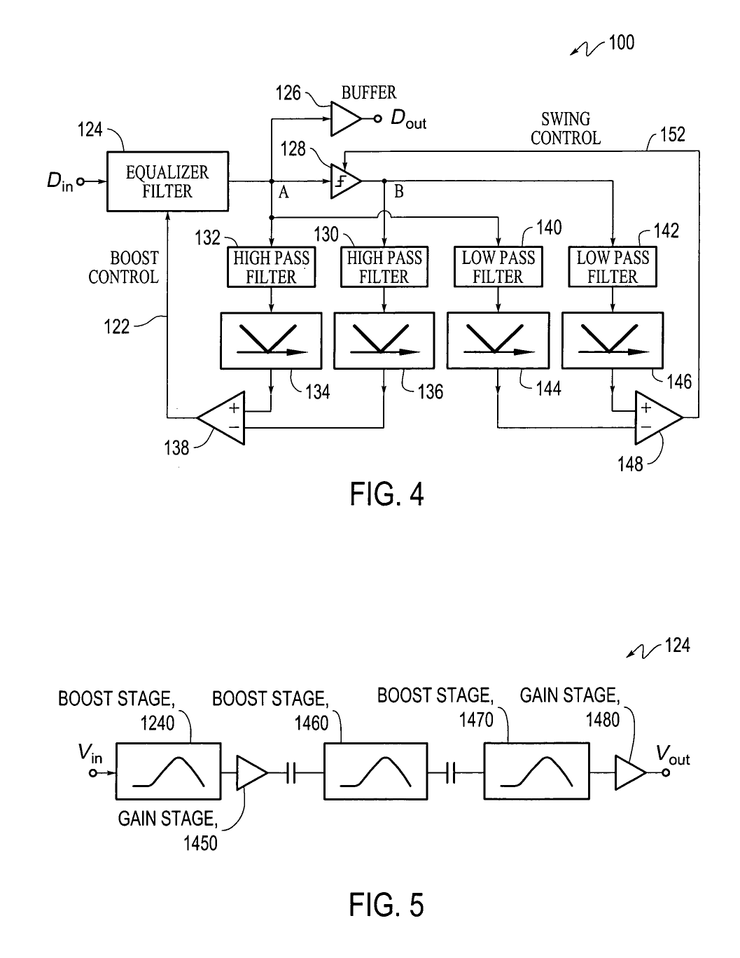

FIG. 4 is a diagram of an exemplary equalizer 100 using dual loop adaptation. A first feedback loop 122 may be configured similarly to the equalizer 20 of FIG. 2. The first feedback loop 122 may generate the boost control input of an equalizer filter 124, based on an output of an operational amplifier 138. Inputs to operational amplifier 138 may be outputs of rectifiers 134 and 136, which may rectify filtered signals from high pass filters 130 and 132. Inputs to high pass filters 130 and 132 may be an input A to slicer 128 and an output B of slicer 128, respectively. Output of equalizer filter 124 may be fed to an output buffer 126.

Since the phase of the channel is linear, equalizer filter 124 may need to have high frequency boost with linear phase. Equalizer filter 124 may comprise at least one boost stage, followed by at least one gain stage. FIG. 5 shows additional detail of an exemplary equalizer filter 124, comprising three boost stages 1240, 1260 and 1270, and two gain stages 1250 and 1280. Boost stages 1240, 1260 and 1280 may apply a frequency-dependent gain to the signal, and gain stages 1250 and 1280 may apply a frequency-independent gain to the signal.

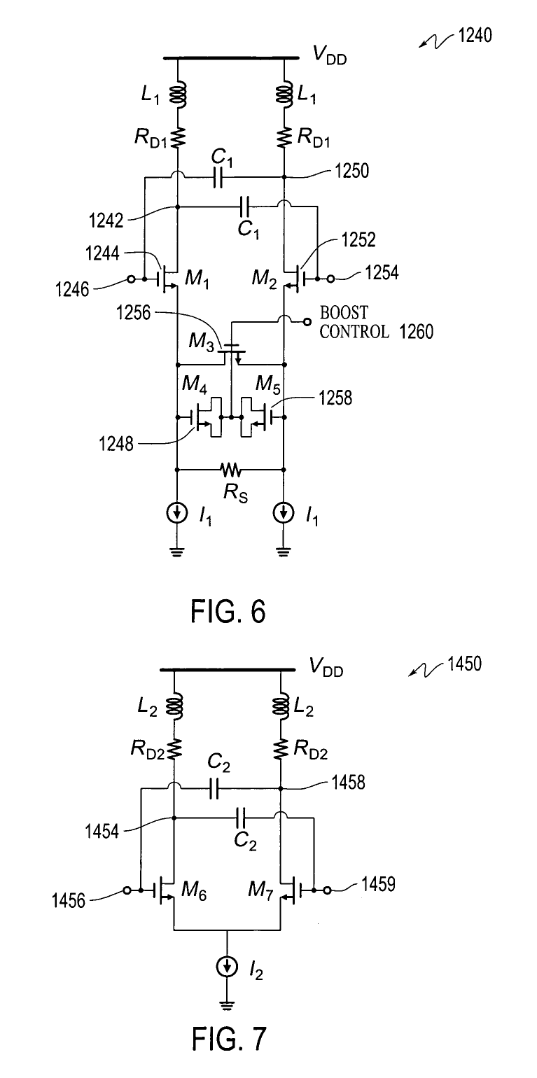

FIG. 6 shows an exemplary equalizer boost stage 1240, which has resonant circuit characteristics. A boost control signal 1260 may adjust the resonant frequency and Q (Quality factor) of the boost circuit, in order to amplify signals around the resonant frequency. A differential signal to be equalized may be input at nodes 1246 and 1254 into input transistors M1 1244 and M2 1252. Boost control signal 1260 may be input to a gate of transistor M3 1256, and also to drains of transistors M4 1248 and M5 1258. Since the voltage on the gate of transistor M3 1256 may control the resistance across M3 1256, the transistor M3 1256 may operate as a variable resistor. The voltage applied to the drains of transistors M4 1248 and M5 1258 may alter the capacitance between the gate and drain, such that transistors M4 1248 and M5 1258 operate as voltage-variable capacitors, or varactors. Therefore, by adjusting the voltage on the boost control signal 1260, the resistance of M3 1256 and the capacitance of M4 1248 and M5 1258 may be adjusted. This may adjust the high frequency characteristics of the circuit. For example, depending on the value of the boost control signal 1260, the boost stage may amplify frequencies in excess of 500 MHz.

The differential output of the boost circuit may be taken at nodes 1242 and 1250. The differential output of the boost circuit may then be amplified by a frequency-independent gain stage 1450. FIG. 7 shows additional detail of the gain stage 1450. Gain stage 1450 may include at least two transistors M6 1454 and M7 1458. The differential input signal may be applied to input nodes 1451 and 1457, respectively, from output nodes 1242 and 1250 of boost stage 1240 of FIG. 6. Output from gain stage 1450 may be taken from nodes 1454 and 1458, which may then be input to a next boost stage 1460 (see FIG. 5). Gain stage 1450 may provide a frequency independent gain of about 1.7 to 1.8, or of approximately 2, across all frequencies. The amount of gain provided by gain stage 1450 may be a function of the size of M6 1454 and M7 1458, the resistance value R_{D2}, and the amplifier bias current 12.

Additional details of the exemplary equalizer boost stage 1240 and frequency-independent gain stage 1450 may be found in related application Ser. No. ______ (Attorney Docket No. 121449), incorporated herein by reference in its entirety.

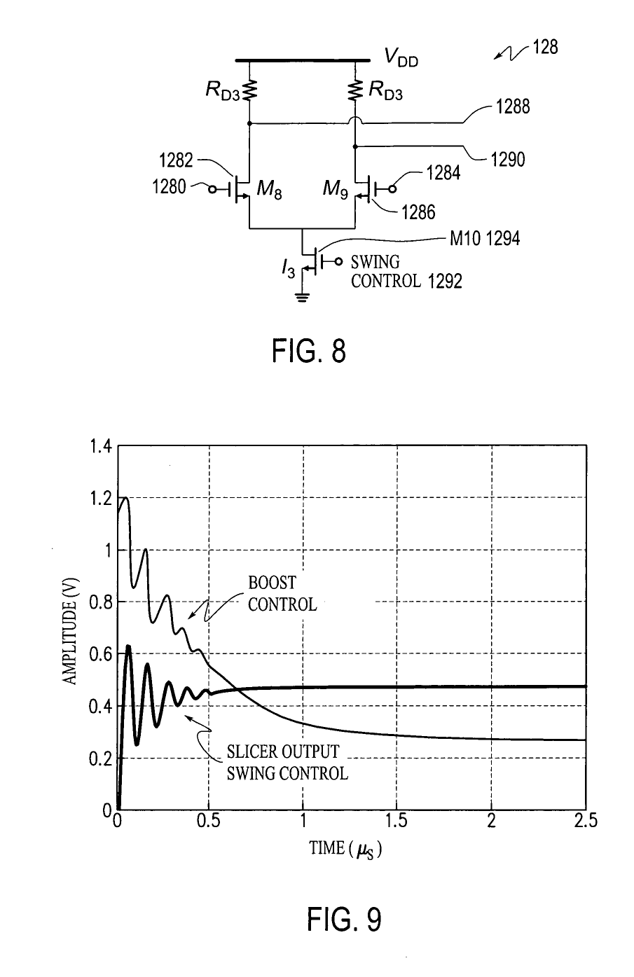

The slicer 128 (FIG. 4) may be a saturating gain stage similar to gain stage 1450, which decides if the received bit was a logical “1” or a logical “0”. Additional details of the exemplary slicer 128 are shown in FIG. 8. The slicer 128 may include two transistors M8 1282 and M9 1286, which accept a differential input signal on nodes 1280 and 1284, respectively. When the input signal to node 1280 is high, transistor M8 1282 is turned on, and may conduct current from voltage supply VDD to ground. Turning on transistor M8 1282 therefore may lower the voltage at output node 1288. Similarly, when input signal to node 1284 is high, transistor M9 1286 is turned on, and may conduct current from voltage supply V_{DD} to ground. Turning on transistor M9 1284 therefore lowers the voltage at output node 1290. Therefore, the differential output of slicer 128 is a signal that swings between +I₃R_{D3} and −I₃R_{D3}, depending, in part, on the magnitude of the differential input signal. It should understood from FIG. 8 that the output of slicer 128 may be an inverted signal, which may go from a positive maximum to a negative maximum each time the input signal on nodes 1280 or 1284 exceeds a certain minimum amplitude. As is evident from FIG. 8, the swing of the slicer may be determined by parameters such as the tail current I₃, of the slicer. The tail current may be adjusted by adjusting the gate voltage on transistor M10 1294, for example, using swing control signal 1292.

It should be understood that boost stage 1240, gain stage 1450, and slicer 128 shown in FIGS. 6-8, respectively, are only examples of boost stages, gain stages and slicers which may be employed in circuit 100, and any of a number of various other circuits may be used.

Referring again to FIG. 4, in addition to feedback loop 122, there may be a second, additional feedback loop 152, which feeds back a swing control signal that controls the swing of slicer 128, for example via a variable resistor such as mentioned above. The swing control signal may be output from a second operational amplifier 148, which may output a signal dependent upon the difference between its inputs. Inputs to operational amplifier 148 may be outputs of rectifiers 144 and 146, which rectify filtered signals from low pass filters 140 and 142. Inputs to low pass filters 140 and 142 may be the input A to slicer 128 and the output B of slicer 128.

Low pass filters 140 and 142 may have cutoff frequencies of less than 400 MHz, compared to the cutoff frequencies of the high pass filters 130 and 132, which may be in excess of 4 GHz. More generally, low pass filters 140 and 142 may pass frequencies lower than about 1 GHz, and high pass filters 130 and 132 may pass frequencies higher than about 1 GHz.

The swing control signal may adjust the output B of slicer 128 until the low pass filtered, rectified output B of slicer 128 is equal to the low pass filtered, rectified input A to slicer 128. For example, the second feedback loop 152 may generate a swing control signal that may increase or decrease the swing of slicer 128 if the operational amplifier detects a difference between its negative (inverting) input compared to its positive (non-inverting) input. The second feedback loop 152 may thereby eliminate the second source of error illustrated in FIG. 3.

The swing control feedback loop 152 may be used to control the swing of other reference signals derived from other parts of the circuit, not just the slicer 128. For example, a swing control feedback loop may be applied to clock and data recovery (CDR) circuits, indicated by reference number 140 in FIG. 1.

Since, in FIG. 4, two feedback loops, boost control feedback loop 122 and swing control feedback loop 152, may be operating on the same signal, it is possible that they may interact with one another, for example, one increasing the boost control to increase the swing of the signal at input A to slicer 128, and the other simultaneously decreasing the swing of output B of slicer 128. These interactions may be avoided by making the settling times for each respective loop substantially different. For example, the settling time for swing control loop 152 may be made much shorter than the settling time for the boost control loop 122. Using this approach, the swing control of slicer 128 may be corrected and the corrected value may have settled, before boost control feedback loop 122 acts upon the signal of equalizer filter 124. This feature is illustrated in FIG. 9. FIG. 9 shows swing control loop 152 settling in between about 0.5 μsec and 1.0 μsec, and boost control loop 122 settling between about 1.5 μsec and 2.0 μsec. Thus, by making the settling times between the two feedback loops substantially different, possible interactions between the two loops may be avoided.

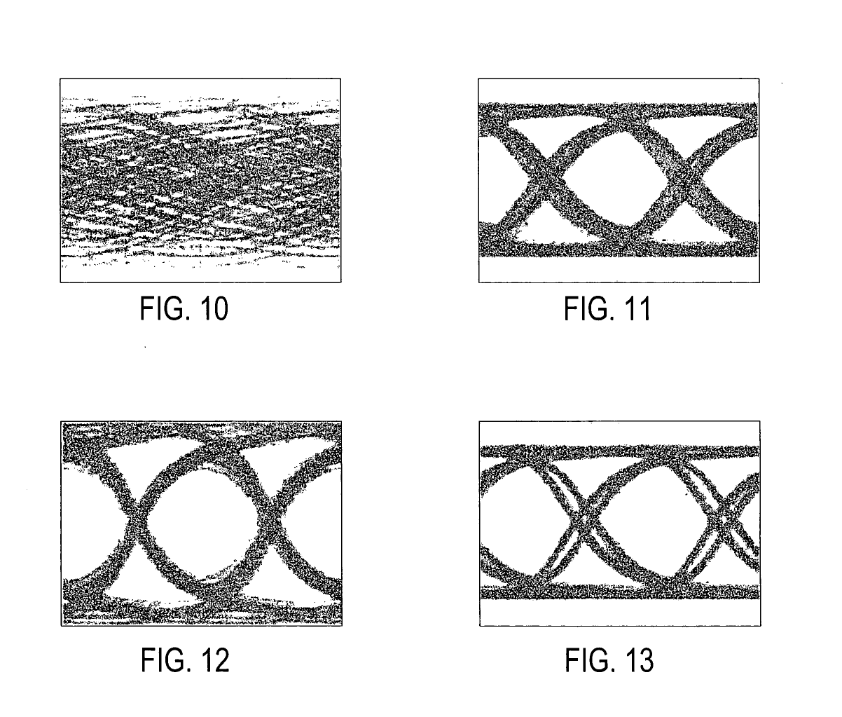

FIGS. 10-13 show experimental results of an equalizer using dual feedback loops on a signal having a maximum data rate of 10 Gb/sec. The supply voltage for FIGS. 10-13 was 1.2V. FIG. 10 shows the 10 Gb/sec signal at the output of a 30 inch channel, and FIG. 12 shows the 10 Gb/sec signal at the output of a 6 inch channel. The channels were fabricated using Flame Retardant 4 (FR4), a fiberglass material widely used in the manufacture of printed circuit boards. As shown in FIGS. 10 and 12, the 30 inch channel may significantly attenuate the high frequency attributes of the signal, leading to severe intersymbol interference, and the 6 inch channel may similarly attenuate the high frequency attributes, although less severely. The signal shown in FIG. 10, if put into a clock recovery circuit, may result in significant phase jitter of the clock.

FIGS. 11 and 13 show the signals from FIGS. 10 and 12, respectively, after equalization in an equalizer using dual feedback loops, such as that shown in FIG. 4. As shown in FIGS. 11 and 13, the high frequency characteristics of the signal may be largely restored by the equalizer, leading to much improved bit error rate performance at the data detector.

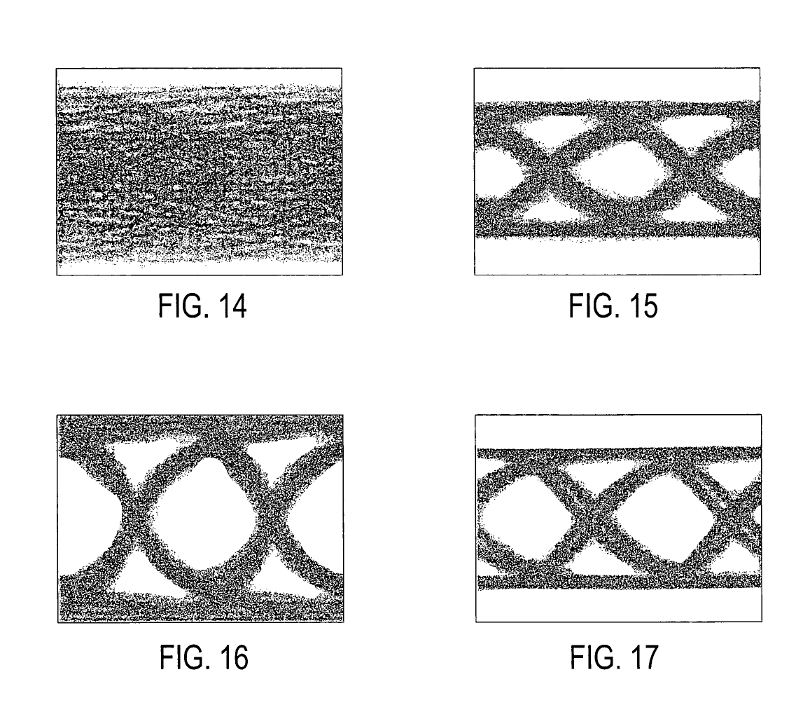

FIGS. 14-17 also show experimental results of an equalizer using dual feedback loops on a signal having a maximum data rate of 10 Gb/sec. The supply voltage for FIGS. 14-17 was 1.0 V, rather than the 1.2 V shown in FIGS. 10-13. FIG. 14 shows the 10 Gb/sec signal at the output of a 30 inch FR4 channel, and FIG. 16 shows the 10 Gb/sec signal at the output of a 6 inch FR4 channel. As shown in FIGS. 14 and 16, the 30 inch channel may significantly attenuate the high frequency attributes of the signal, leading to severe intersymbol interference, and the 6 inch channel may similarly attenuate the high frequency attributes, although less severely. The signal shown in FIG. 14, if put into a clock recovery circuit, may result in significant phase jitter of the clock.

FIGS. 15 and 17 show the signal from FIGS. 14 and 16, respectively, after equalization in an equalizer using dual feedback loops, such as that shown in FIG. 4. As shown in FIGS. 15 and 17, the high frequency characteristics of the signal may have been largely restored by the equalizer, leading to much improved bit error rate performance at the data detector.

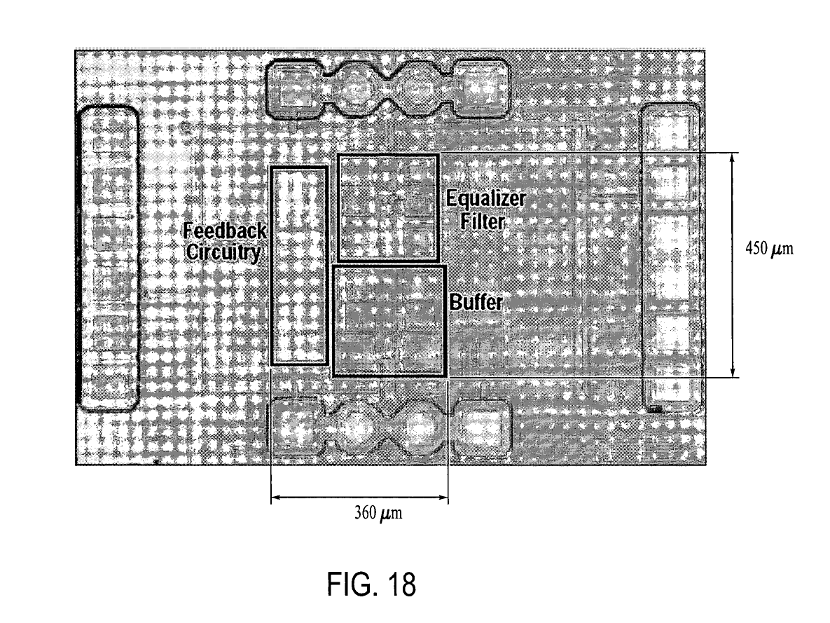

FIG. 18 is a photograph of the exemplary equalizer 100 taken through a microscope, such that the features have the characteristic dimensions shown in FIG. 18. As shown in FIG. 18, the overall size of the CMOS equalizer is about 450×360 μm, including the buffers and feedback circuitry.

Table 1 below summarizes some experimental performance results of the dual feedback adaptive equalizer 100 shown in FIG. 4 and in FIG. 18. As shown in Table 1, the dual loop equalizer may consume only 25 mW of power from the 1.2 V supply, and may have less than 9 mVᵣₘₛ residual noise. Due to its relatively small size and low power consumption, the dual loop adaptive equalizer may be suitable for a variety of applications.

TABLE 1

| Parameter | Value |
|---|---|
| Max data rate | 10 Gb/sec |
| Loss compensated | 20 dB @ 5 GHz |
| RMS noise | <9 mVᵣₘₛ |
| Power supply | 1.0-1.2 V |
| Power consumption | 16-25 mW |
| Die area | 450 μm × 360 μm |
| Technology | 0.13 μm CMOS |

While various details are described in conjunction with the example outlined above, it is evident that many alternatives, modifications and variations are possible. For example, the dual loop adaptation techniques described herein are applicable to analog as well as digital equalizers. In addition, other feedback loops may be applied to other reference signals in the circuit, such as to a clock and data recovery circuit. Accordingly, the exemplary implementations as set forth above are intended to be illustrative, not limiting.

What is claimed is:

1. An adaptive equalizer, comprising:
an equalizer filter that provides an equalized waveform;
a boost control feedback loop, that controls a boost of the equalizer filter;
a slicer that produces a high output level when the equalized waveform exceeds a certain positive threshold and produces a low output level when the equalized waveform threshold exceeds a negative threshold; and
a swing control feedback loop that controls the high output level and the low output level of the slicer.

2. The equalizer of claim 1, wherein the boost control feedback loop further comprises at least two high pass filters that respectively filter an input and an output of the slicer.

3. The equalizer of claim 2, further comprising at least two rectifiers, that rectify outputs of the at least two high pass filters.

4. The equalizer of claim 3, further comprising:
an operational amplifier having inputs coupled to outputs of the at least two rectifiers, the operational amplifier outputting a signal to equalize the inputs.

5. The equalizer of claim 1, wherein the swing control feedback loop further comprises at least two low pass filters that respectively filter an input and an output of the slicer.

6. The equalizer of claim 5, further comprising at least two rectifiers that rectify outputs of the at least two low pass filters.

7. The equalizer of claim 6, further comprising:
an operational amplifier having inputs coupled to the outputs of the at least two rectifiers.

8. The equalizer of claim 1, wherein the equalizer filter further comprises:
an inductor;
an output capacitor; and
at least two transistors, a first transistor configured as a variable resistor and a second transistor configured as a variable capacitor, the first and the second transistors interacting with the inductor and the output capacitor to form a boost circuit having resonant characteristics.

9. The equalizer of claim 8, wherein the equalizer filter further comprises:
a frequency-independent gain stage, coupled to the boost circuit.

10. A method of producing an equalized signal from a channel, comprising:
equalizing a signal from a channel in an equalizer filter;
slicing the equalized signal in a slicer;
generating a first feedback signal based on the equalized signal and the sliced signal, and controlling the equalizer based on the first feedback signal; and
generating a second feedback signal based on the equalized signal and the sliced signal, and controlling the slicer based on the second feedback signal.

11. The method according to claim 10, wherein generating the first feedback signal further comprises high pass filtering the equalized signal and the sliced signal.

12. The method according to claim 11, wherein generating the first feedback signal further comprises rectifying the high pass filtered equalized signal and high pass filtered sliced signal.

13. The method of claim 12, wherein controlling the equalizer further comprises:
adjusting the equalizer until the rectified, high pass filtered equalized signal substantially equals the rectified, high pass filtered sliced signal.

14. The method of claim 10, wherein generating the second feedback signal further comprises low pass filtering the equalized signal and the sliced signal.

15. The method of claim 14, wherein generating the second feedback signal further comprises rectifying the low pass filtered equalized signal and low pass filtered sliced signal.

16. The method of claim 15, wherein controlling the slicer further comprises:
adjusting a swing of the slicer until the rectified, low pass filtered sliced signal substantially equals the rectified, low pass filtered equalized signal.

17. The method of claim 10, wherein equalizing the signal further comprises:
adjusting a variable resistor and a variable capacitor to adjust a high frequency characteristic of a boost circuit to produce a boosted output signal.

18. The method of claim 17, wherein equalizing the signal further comprises:
amplifying the boosted output signal to provide the equalized signal.

19. An apparatus for producing an equalized signal from a channel, comprising:
means for equalizing a signal from a channel in an equalizer;
means for slicing the equalized signal;
means for generating a first feedback signal based on the equalized signal and the sliced signal;
means for controlling the equalizer based on the first feedback signal;
means for generating a second feedback signal based on the equalized signal and the sliced signal; and
means for controlling the slicer based on the second feedback signal.
